(19) United States
(12) Patent Application Publication
(10) Pub. No.: US 2016/0336307 A1
(43) Pub. Date: Nov. 17, 2016

(54) SEMICONDUCTOR COMPONENT AND METHOD OF PRODUCING A SEMICONDUCTOR COMPONENT

(71) Applicant: OSRAM Opto Semiconductors GmbH, Regensburg (DE)

(72) Inventors: Siegfried Herrmann, Neukirchen (DE); Stefan Illek, Donaustauf (DE); Frank Singer, Regenstauf (DE)

(21) Appl. No.: 15/112,765

(22) PCT Filed: Jan. 16, 2015
(86) PCT No.: PCT/EP2015/050781

§ 371 Date: Jul. 20, 2016

(30) Foreign Application Priority Data
Jan. 23, 2014 (DE) 10 2014 100 773.5

(51) Int. Cl. H01L 27/02; H01L 33/48; H01L 33/60; H01L 33/00; H01L 33/54; H01L 33/38; H01L 33/62; H01L 25/16; H01L 33/50

(52) U.S. Cl. CPC H01L 27/0248; H01L 25/167; H01L 33/486; H01L 33/60; H01L 33/502; H01L 33/54; H01L 33/382; H01L 33/62; H01L 33/0079; H01L 2933/0033; H01L 2933/0058; H01L 2933/0066; H01L 2933/0016; H01L 2933/0041; H01L 2933/005

(57) ABSTRACT

A method of producing a semiconductor component includes providing a carrier with a first insulation layer, a mirror layer at least partially covered by the first insulation layer and a connection element, wherein the carrier includes an exposed planar mounting surface and the connection element extends through the first insulation layer to the mounting surface, providing a main body with a semiconductor body, a second insulation layer and a contact element to electrically contact the semiconductor body, wherein the main body has an exposed planar contact surface and the contact element extends through the second insulation layer to the contact surface, and connecting the main body to the carrier, wherein the planar contact surface and the planar mounting surface are brought together to form a connecting surface, and the contact element and the connection element electrically connect with one another.

### TECHNICAL FIELD

This disclosure relates to a semiconductor component and a method of producing a semiconductor component.

### BACKGROUND

The electrical contacting of a flip chip component is known from U.S. Pat. No. 8,427,839 B2 in which the production of mechanical connections between a flip chip and a carrier as well as of electrical connections between the electrical contacts is on the basis of a soldering or adhesive technology. The use of an electrically conductive connecting material can lead to a short circuit of the flip-chip component. In particular, in the event of mass production, fewer scrapped components are an important factor in reducing manufacturing costs.

There is thus a need to provide a reliable method of producing a semiconductor component that allows a mechanical as well as an electrical connection between a main body and a carrier of the semiconductor component to be easily and reliably achieved, as well as a semiconductor component having a simplified contacting structure and a high mechanical stability.

### SUMMARY

We provide a method of producing a semiconductor component including:
A) providing a carrier with a first insulation layer, a mirror layer at least partially covered by the first insulation layer and a connection element, wherein the carrier includes an exposed planar mounting surface and the connection element extends through the first insulation layer to the mounting surface,
B) providing a main body with a semiconductor body, a second insulation layer and a contact element to electrically contact the semiconductor body, wherein the main body has an exposed planar contact surface and the contact element extends through the second insulation layer to the contact surface, and
C) connecting the main body to the carrier, wherein the planar contact surface and the planar mounting surface are brought together to form a connecting surface, and the contact element and the connection element electrically connect with one another.

We also provide a semiconductor component including a carrier, a main body arranged on the carrier and a through-contacting structure, in which the carrier has a first insulation layer, a mirror layer at least partially covered by the first insulation layer and a connection element extending through the first insulation layer, wherein the mirror layer is flat and, in top view, projects laterally beyond the main body, the main body has a semiconductor body, a second insulation layer and a contact element extending through the second insulation layer, the carrier and the main body connect together on the insulation layers, wherein a connecting surface is formed between the insulation layers, the connecting surface being devoid of any connecting material, and the through-contacting structure extends in the vertical direction through the carrier and includes the connection element as well as the contact element, wherein the connection element and contact element are adjacent to each other on the connecting surface.

We further provide a semiconductor component including a carrier, a main body arranged on the carrier and a through-contacting structure, in which the carrier has a first insulation layer and a connection element extending through the first insulation layer, the main body has a semiconductor body, a second insulation layer and a contact element extending through the second insulation layer such that a contact surface is formed by surfaces of the contact element and of the second insulation layer, the carrier and the main body connect together on the insulation layers, wherein a connecting surface is formed between the first and the second insulation layers, the connecting surface is formed by the contact surface and is devoid of connecting material, and the through-contacting structure extends in the vertical direction through the carrier and includes the connection element and the contact element, wherein the connection element and contact element are adjacent to each other on the connecting surface.

### BRIEF DESCRIPTION OF THE DRAWINGS

FIG. 1A is a sectional view of an example of a method of producing a semiconductor component with a carrier and a main body.

FIGS. 1B to 1D are various examples of the carrier of the semiconductor component in top view.

FIGS. 2A to 2C are schematic sectional views of various stages of the procedure of an example of producing a main body of the semiconductor component.

FIGS. 3A and 3B are an example of a semiconductor component.

FIGS. 4a to 7 are sectional views of further examples of a semiconductor component.

### DETAILED DESCRIPTION

We provide a method of producing a semiconductor component, a carrier and a main body. The carrier may have a first insulation layer. For example, the insulation layer is an oxide layer, in particular a silicon oxide layer. For example, the first insulation layer is formed on a supporting body of the carrier. The carrier has at least one electrically conductive connection element. The connection element extends in a vertical direction throughout the first insulation layer. A vertical direction is a direction in particular running perpendicular to a main extension plane of the carrier.

A mirror layer may be embedded in the first insulation layer. In top view on the supporting body, the mirror layer is at least partially covered by the first insulation layer. In particular, the mirror layer is completely embedded in the first insulation layer. In other words, the mirror layer is enclosed on all sides by the first insulation layer. The first insulation layer may have a single-layered or multi-layered fashion.

A surface of the carrier may be formed as a planar mounting surface. In particular, the connection element extends through the first insulation layer to the mounting surface. The planar mounting surface is in particular formed by an exposed surface of the first insulation layer and an exposed surface of the connection element. In particular, the planar mounting surface limits the carrier in a vertical direction. For example, the planar mounting surface is devoid of edges. For example, the planar mounting surface is formed as a contiguous surface of the carrier extending in lateral directions over the entire main extension plane of the carrier. A lateral direction is a direction that in particular runs parallel to the main extension plane of the carrier. The lateral direction and the vertical direction are thus mutually orthogonal. A planar surface is a surface in particular formed in a microscopically flat manner. For example, such a planar surface has a roughness less than 10 nm and in particular less than 1 nm. In particular, such a planar surface is devoid of edges.

A main body may be provided. The main body has in particular a semiconductor body and a second insulation layer arranged on the semiconductor body. The main body has, for example, an exposed planar contact surface. In particular, the planar contact surface limits the main body in a vertical direction. Furthermore, the main body has at least one contact element to electrically contact the semiconductor body. In particular, the contact element extends in the vertical direction through the second insulation layer to the contact surface. In particular, the planar contact surface is formed by an exposed surface of the contact element, stretching in lateral directions, and an exposed surface of the second insulation layer, stretching in lateral directions. In particular, the planar contact surface is contiguously formed. For example, in top view, the planar contact surface completely covers the semiconductor body or the main body.

The main body and the carrier may be connected to one another by a direct bonding method. In particular, the contact surface and the mounting surface are brought together to form a connecting surface. The connecting surface in particular separates the carrier from the main body and vice versa. In particular, the connecting surface and the mounting surface have the same vertical position. The contact element and the connection element electrically connect to one another along the connecting surface, in particular electrically connect directly to one another, for instance without any electrical connecting material such as a solder or an adhesive. For example, the contact element on the connecting surface is adjacent to the connection element. In particular, the connecting surface is an overlap surface resulting from the merger of the contact surface and the mounting surface. For example, the mounting surface is formed to be larger than the contact surface or vice versa. When viewing the carrier from above, for example, the mounting surface projects in lateral directions beyond the contact surface. For example, a focal point of the contact surface and a focal point of the mounting surface are spaced apart from each other in top view.

A carrier and a main body may be provided. The carrier has a first insulation layer, a mirror layer, at least part of which is covered by the first insulation layer, and at least one connection element, wherein the carrier comprises an exposed planar mounting surface and the connection element extends through the first insulation layer to the mounting surface. The main body has a semiconductor body, a second insulation layer and at least one contact element to electrically contact the semiconductor body, wherein the main body has an exposed planar contact surface and the contact element extends through the second insulation layer to the contact surface. The main body connects to the carrier, wherein the planar contact surface and the planar mounting surface are brought together to form a connecting surface, and the contact element and the connection element electrically connect to one another.

Due to the planar shape of the contact surface and mounting surface, the main body and the carrier preferably mechanically connect to one another by a direct bonding method. In such a direct bonding method two bodies, each with a planar surface, are brought together subject to adequate pressure and adequate temperature and mechanically connected to one another on the basis of Van-der-Waals interactions or hydrogen bridge bonds between the atoms on the planar surfaces. The planar surfaces can, for example, be formed by surfaces of a metal and/or an oxide layer. This bonding technology allows in particular a connecting material such as an adhesive or a soldering material, to be waived. The contact element and the connection element directly electrically connect to one another, thus allowing the danger of a short circuit to be largely avoided. Nevertheless, it is also possible that the carrier and the main body connect to one another by an alternative method with a connecting material.

Furthermore, the comparatively complicated wiring of the semiconductor component in the carrier produced separately from the main body can be realized on the basis of the separate production of the contact element in the main body and of the connection element in the carrier that makes production of the wiring of the semiconductor component relatively straightforward. Furthermore, protective elements as well as optical elements to increase the efficiency of the semiconductor component can be integrated in the carrier, thus facilitating a reliable overall production of the semiconductor component.

The connecting surface may be devoid of any connecting material. In particular, the connecting surface forms an interface between the first and second insulation layers as well as between the connection element and the contact element. In particular, the first and second insulation layers each comprise an oxide. The connection element and the contact element each comprise, for example, a metal. The connecting surface is in particular partially formed by an oxide-oxide, a metal-metal and an oxide-metal interface.

The mirror layer may be completely embedded in the first insulation layer. The mirror layer is thus in particular protected against environmental influences. The mirror layer can be formed in an electrically conductive or electrically insulating manner. In particular, the mirror layer is structured and has one or more openings.

The mirror layer may be formed so large that, after connecting the carrier to the main body, the mirror layer projects laterally on all sides beyond the main body when viewing the carrier from above. In particular, the mirror layer has a base surface bigger than a base surface of the main body. For example, the mirror layer is flat. A flat layer or a flat surface means that the latter has no local elevations or depressions, other than openings within the scope of the production tolerances. In particular, the mirror layer is formed parallel to the mounting surface.

The semiconductor body may have a first semiconductor layer, a second semiconductor layer and an active area arranged between the first semiconductor layer and the second semiconductor layer. In particular, the active area emits or detects electromagnetic radiation. For example, the semiconductor component is formed as an optoelectronic semiconductor component.

At least one further contact element may be introduced into the main body. The further contact element extends in particular from the contact surface through the second insulation layer, the first semiconductor layer and the active area into the second semiconductor layer. In particular, the further contact element is completely laterally surrounded in at least a vertical position by the semiconductor body, in particular by the active area.

The contact element and the further contact element in particular electrically contact the semiconductor body. The contact element is, for example, adjacent to the first semiconductor layer. The further contact element extends in particular through the first semiconductor layer and the active area into the second semiconductor layer. The semiconductor body can be externally contacted via the contact element and the further contact element. In particular, load carriers can reach the active area via the contact element and the further contact element from various sides and recombine there while emitting radiation.

After connecting the main body to the carrier, a converter layer may be attached such that, in top view, the converter layer completely covers the main body and at least partially covers areas of the mirror layer laterally relative to the main body. For example, the converter layer is attached to the main body and to the carrier by spraying, casting or dispensing.

The semiconductor body may be attached to a growth substrate in layers, in particular epitaxially deposited. In the next procedural step the growth substrate is, for example, thinned, structured or completely removed from the semiconductor body.

A semiconductor component may comprise a carrier, a main body with a semiconductor body arranged on the carrier and a through-contacting structure. The through-contacting structure electrically contacts the semiconductor body. In particular, the through-contacting structure extends in the vertical direction through the carrier into the main body. The semiconductor component can in particular be externally contacted electrically by the through-contacting structure on a rear side of the carrier facing away from the main body.

A connecting surface may be formed between the carrier and the main body, the connecting surface being in particular devoid of any connecting material. A mechanical connection between the carrier and the main body on the connecting surface is, for example, established by a direct bonding method. The connecting surface is formed in a flat, in particular, planar manner.

The semiconductor component may have a carrier, a main body and a through-contacting surface. The carrier has a first insulation layer, a mirror layer covered at least in part by the first insulation layer, and a connection element extending through the first insulation layer. The mirror layer is flat and, in top view, projects laterally beyond the main body. The main body has a semiconductor body, a second insulation layer and a contact element extending through the second insulation layer. The carrier and the main body connect to one another on the insulation layers, wherein a connecting surface is formed between the insulation layers. The through-contacting structure extends in a vertical direction through the carrier. The through-contacting structure comprises at least the connection element and the contact element, wherein the connection element and contact element are adjacent to each other on the connecting surface and electrically connect to one another. In particular, the connecting surface is devoid of any connecting material.

The carrier may have a further connection element extending through the first insulation layer and spatially set apart from the connection element in the lateral direction.

The semiconductor component may have a first semiconductor layer, a second semiconductor layer and an active area arranged between the semiconductor layers. The main body has at least one further contact element to electrically contact the semiconductor body, which extends from the connecting surface in particular through the second insulation layer, the first semiconductor layer and the active area into the second semiconductor layer. Another possible alternative is that the further contact element is arranged laterally relative to the semiconductor body and extends in a vertical direction from the connecting surface to the second semiconductor layer.

The mirror layer may be formed in an electrically insulating manner. Nevertheless, the mirror layer can be formed in an electrically conductive manner. To electrically insulate the connection element from the mirror layer, for example, a connecting insulation can be formed in an opening of the mirror layer, through which the connection element extends. The further connection element can be in direct electrical contact with the mirror layer. Another possibility is that the mirror layer is formed in an electrically conductive manner and has two parts, wherein the two parts of the mirror layer are spatially set apart in the lateral direction by a connecting insulation and the two parts of the mirror layer are each in direct electrical contact with the connection element or with the further connection element.

The further contact element may have a lateral cross section that, for example, tapers in a vertical direction from the first semiconductor layer towards the second semiconductor layer. The further contact element has a flank that forms an acute angle with a vertical of the connecting surface on the connecting surface which angle, for example, equals a maximum of 10°, in particular a maximum of 5°. The cross section of the contact element has a diameter on the connecting surface equaling, for example, a maximum of 40 μm, in particular a maximum of 20 μm. For example, the diameter is at least 3 μm, in particular at least 15 μm. Such a contact element reduces the proportion of electromagnetic radiation that impacts the further contact element and is absorbed by the latter.

The semiconductor component may have a converter layer. Viewed from above, the converter layer covers the main body in particular completely and, for example, parts of the mirror layer laterally relative to the main body at least partially. The converter layer contains, for example, a luminescent material, for instance in the form of particles that converts radiation with a first dominant wavelength into radiation with a second dominant wavelength. If the converted radiation impacts areas of the mirror layer laterally relative to the main body, the radiation is reflected in the direction of a radiation exit side of the semiconductor component, thus increasing the efficiency of the semiconductor component with regard to out-coupling in a stipulated emission direction. The semiconductor component may have a layer on lateral flanks of the main body, in particular the converter layer with reflecting or scattering particles, for instance titanium oxide particles, thus additionally increasing the radiation out-coupling degree of the semiconductor component in a stipulated emission direction.

The semiconductor component may have a protective element, in particular as protection against electrostatic discharge. The protective element is, for example, integrated within the carrier. For example, the protective element electrically interconnects in parallel with the semiconductor body via the through-contacting structure.

The main body may have a growth substrate. In particular, the semiconductor body is deposited in layers on the growth substrate. The growth substrate has in particular a surface facing the semiconductor body with light decoupling structural elements. The growth substrate is, for example, a structured sapphire substrate.

The semiconductor component may have an optical element. In particular, in a top view, the optical element completely covers the main body, the converter layer and the mirror layer. For example, the optical element completely covers the mounting surface of the carrier.

The method is particularly suitable for producing a previously described semiconductor component. Features described in conjunction with the semiconductor component can thus also be used for the method and vice versa.

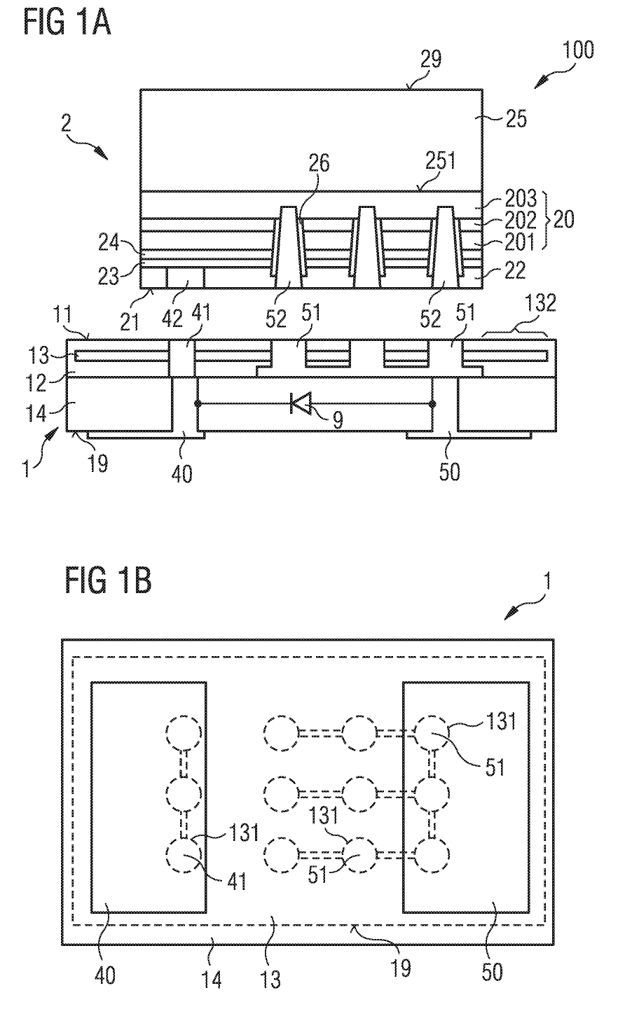

Further advantages and developments of the semiconductor component as well as of the method result from the examples explained in the following in conjunction with FIGS. 1A to 7.

Identical, similar or apparently identical elements are furnished with the same reference signs in the illustrations. The illustrations are always schematic diagrams and therefore not necessarily true-to-scale. For reasons of clarification, comparatively small elements and in particular layer thicknesses can instead be shown exaggeratedly large, for example, at the step transitions of the layers.

FIGS. 1A to 1D show a first example of a method of producing a semiconductor component 100.

FIG. 1A provides a carrier 1. The carrier 1 has a supporting body 14. The supporting body 14 can contain a semiconductor material, in particular silicon, or be formed as a silicon body. The carrier 1 has a first insulation layer 12. The first insulation layer 12 is formed on the supporting body 14. The carrier 1 has at least one connection element 41 and a further connection element 51 laterally spaced apart from the connection element 41. The connection element 41 and the further connection element 51 extend through the first insulation layer 12 in the vertical direction. The carrier 1 has a rear side 19 facing away from the first insulation layer 12, with a further connection surface 50 laterally spaced apart from the connection surface 40. The connection element 41 electrically connects to the connection surface 40 via an opening in the carrier body 14. The further connection element 51 electrically connects to the further connection surface 50 via a further opening in the supporting body 14.

The carrier 1 has an exposed planar mounting surface 11. The planar mounting surface 11 faces away from the rear side 19 of the carrier 1. The carrier 1 has a plurality of connection elements 41 and further connection elements 51. The planar mounting surface 11 is formed by exposed surfaces of the first insulation layer 12, of the connection elements 41 and of the further connection elements 51. The planar mounting surface 11 is in particular a contiguous surface of carrier 1.

The carrier 1 has a mirror layer 13. The mirror layer 13 is embedded in the first insulation layer 12. The high planarity of the mounting surface 11 and of the contact surface 21 allows in particular air gaps between the carrier 1 and the main body 2 to be avoided.

For example, the mirror layer 13 in the carrier 1 can be optically coupled without any air gap. The radiation generated by the active area 202 can thus reach the mirror layer 13 without disruption, for example, without Fresnel losses. In particular, the mirror layer 13 can be merely partially or completely covered by the first insulation layer 12. The mirror layer 13 is in particular completely encapsulated by the first insulation layer 12. The mirror layer 13 in FIG. 1A is flat. The mirror layer 13 is aligned parallel to the mounting surface 11.

FIG. 1A provides a main body 2. The main body 2 has a growth substrate 25, a sapphire substrate, for example. The growth substrate 25 has a surface 251 onto which a semiconductor body 20 is in particular applied in layers. The semiconductor body 20 has a first semiconductor 201 of a first load carrier type, a second semiconductor layer 203 of a second load carrier type and an active area 202 arranged between the semiconductor layers. For example, the second semiconductor layer 203 is formed in an n-conducting manner and the first semiconductor layer 201 in a p-conducting manner or vice versa. The semiconductor layers 201 and 203 as well as the active area 202 can all be of single-layered or multi-layered fashion. For example, the active area 202 generates electromagnetic radiation. In particular, the semiconductor component is an optoelectronic semiconductor component. The growth substrate 25 has a surface facing away from the semiconductor body 20, and the surface can serve as a radiation exit surface 29 of the semiconductor component 100.

The main body 2 has a further mirror layer 24. The mirror layer 24 is adjacent to the semiconductor body 20. The radiation generated by the active area 202 can be reflected towards the further mirror layer 24 in the direction of the radiation exit surface to increase the out-coupling efficiency. In particular, the further mirror layer 24 simultaneously serves as a large-scale electrical contact layer for the semiconductor layer 201. The main body 2 has an intermediate layer 23 adjacent to the further mirror layer 24. The intermediate layer 23 is in particular formed as a current expansion layer. The main body 2 has a second insulation layer 22. The intermediate layer 23 is arranged between the second insulation layer 22 and the further mirror layer 24. For example, the further mirror layer 24 comprises silver. The intermediate layer 23 simultaneously serves in particular as an encapsulation for the further mirror layer 24, thus protecting the further mirror layer 24 against environmental influences, for example, humid conditions or noxious gases.

The main body has at least one contact element 42 and at least one further contact element 52 to electrically contact the semiconductor body 20. The contact element 42 extends through the second insulation layer 22. The contact element 42 is in particular provided to electrically contact the first semiconductor layer 201, in particular via the further mirror layer 24. To electrically contact the second semiconductor layer 203, the further contact element 52 extends through the second insulation layer 22, the intermediate layer 23, the further mirror layer 24, the first semiconductor layer 201 and the active area 202 into the second semiconductor layer 203. A contact insulation 26 is formed to insulate the further contact element 52 against the active area 202, the first semiconductor layer 201, the further mirror layer 24 and against the intermediate layer 23, wherein the contact insulation 26 laterally surrounds the further contact element 52 on all sides. The further contact element 52 is completely enclosed at a vertical position by the semiconductor body 20 in the lateral direction. The main body 2 has a plurality of further contact elements 52 spatially set apart from one another in the lateral direction. The main body 2 can have a plurality of contact elements 42.

The main body 2 has an exposed planar contact surface 21. The planar contact surface 21 is formed by exposed surfaces of the second insulation layer 22, of the contact element 42 and of the further contact element 52. The semiconductor body 20 can thus be electrically contacted on the contact surface 21 via the contact element 42 and the further contact element 52. The planar contact surface 21 is, for example, a contiguous exposed surface of the main body 2. The main body 2 and the carrier 1 connect to one other on the planar contact surface 21 and the planar mounting surface 11.

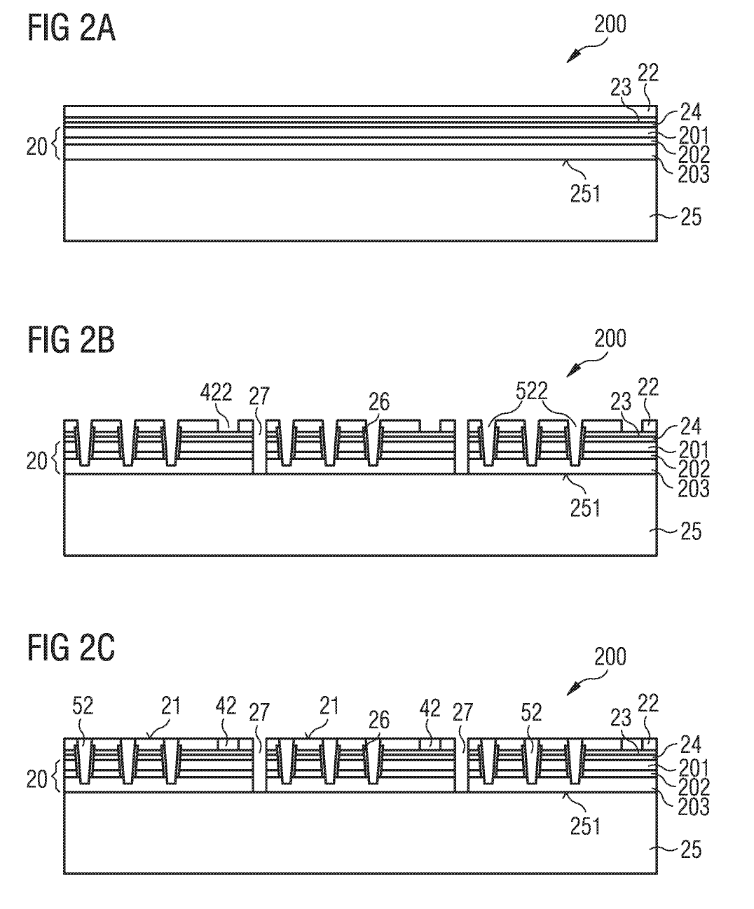

A direct bonding method is preferably used to produce a mechanical connection between the carrier 1 and the main body 2. The planar contact surface 21 of the main body 2 and the planar mounting surface of the carrier 1 are brought together to form a connecting surface 3 as shown in FIG. 3A in the direct bonding method. The mechanical connection between the carrier 1 and the main body 2 on the connecting surface 3 is in particular attributable to the interactions, for example, Van-der-Waals interactions or to the hydrogen bridge bonds between the atoms on the merged, planar contact surface 21 and mounting surface 11.

For example, the first and the second insulation layers 12 and 22 each comprise an oxide, in particular a silicon oxide (SiO₂). The connection element 41 and the contact element 42 can each comprise a metal, for instance copper. Likewise, the further connection element 51 and the further contact element 52 each comprise a metal, in particular copper. This connecting surface 3 is in particular partially formed by an oxide-oxide, a metal-metal and an oxide-metal interface. The stability of the mechanical connection between the carrier 1 and the main body 2 is based in particular mainly on the interactions between the atoms on the oxide-oxide interface. The interactions between the atoms on the metal-metal interface, in particular on a copper-copper interface, and on the oxide-metal interface, in particular on a copper-silicon oxide interface, contribute towards increasing the stability of the mechanical connection between the carrier 1 and the main body 2.

The carrier 1 and the main body 2 connect to one another such that the contact element 42 on the connecting surface 2 is adjacent to the connection element 41 and connected to the latter in an electrically conductive manner. The further connection element 51 and the further contact element 52 are adjacent to one another on the connecting surface 3 and connect to one another in an electrically conductive manner. The semiconductor component 100 can thus be externally connected electrically on the rear side 19 of the carrier 1 via a through-contacting structure 4 as shown in FIG. 3A, which has the contact element 42, the further contact element 52, the connection element 41, the further connection element 51, the connection surface 40 and the further connection surface 50.

The carrier 1 has a larger base surface than the main body 2. The mirror layer 13 also has a larger base surface than the main body 2. The carrier 1 and the main body 2 connect to one another such that, when viewing the carrier 1 from above, the mirror layer 13 partially projects laterally beyond the main body on all sides. The radiation emitted by the active area 202, which laterally exits the main body 2, can thus be at least partially reflected in the direction of the radiation exit surface 29 of the semiconductor component 100 by lateral areas 132 of the mirror layer 13. Simulations have demonstrated that the light output can be increased by up to 5% as a result. This enables the waiver of an additional mirror layer in the main body 2, which in top view completely covers the further contact element 52 and is comparatively complicated to produce. The main body 2 can thus merely have a mirror layer, i.e. the further mirror layer 24.

A protective element 9, in particular an ESD diode, is integrated in the supporting body 14 of the carrier 1 in FIG. 1A. The protective element 9 is completely arranged within the supporting body 14. The protective element 9 electrically interconnects in parallel with the semiconductor body 20 of the main body 2 via the through-contacting structure 4. If the protective element 9 is a diode, for example, the protective element 9 and the semiconductor body 20 can be interconnected antiparallel to one another with regard to the conducting direction thereof.

FIG. 1B shows the carrier 1 when viewing the rear side 19 from above. The carrier has the connection surface 40 and the further connection surface 50 on the rear side 19, which are spaced apart from each other in the lateral direction. The connections surfaces 40 and 50 on the rear side 19 are formed in a flat manner and adjacent to the supporting body 14, which includes, for example, silicon. Such an arrangement improves heat dissipation via the rear side 19 of the carrier 1.

The supporting body 14 has a larger base surface than the mirror layer 13. The mirror layer 13 can be formed in an electrically insulating manner. In such case, the mirror layer is not used for electrical contacting. The mirror layer 13 has a plurality of openings 131. The connection element 41 and the further connection element 51 each extend in the vertical direction through one of the openings 131 of the mirror layer 13.

FIG. 1C shows a schematic diagram of a further example for the carrier 1. The example essentially corresponds to the example shown in FIG. 1B. In contrast thereto, the mirror layer 13 can be formed in an electrically conductive manner. The mirror layer 13 is formed in two parts, wherein one part of the mirror layer 13 is in direct electrical contact with the connection elements 41 and the other part of the reflective layer is in direct electrical contact with the further connection elements 51. The two parts of the mirror layer 13 are electrically insulated against each other by a connecting insulation 16.

FIG. 1D shows a schematic diagram for a further example for the carrier 1. The example essentially corresponds to the example shown in FIG. 1C. In contrast thereto, the mirror layer 13 is formed contiguously. To electrically insulate the connection element 41 against the mirror layer 13, the connection insulation 16 is formed in the respective opening 131, through which the connection element 41 extends through the mirror layer 13.

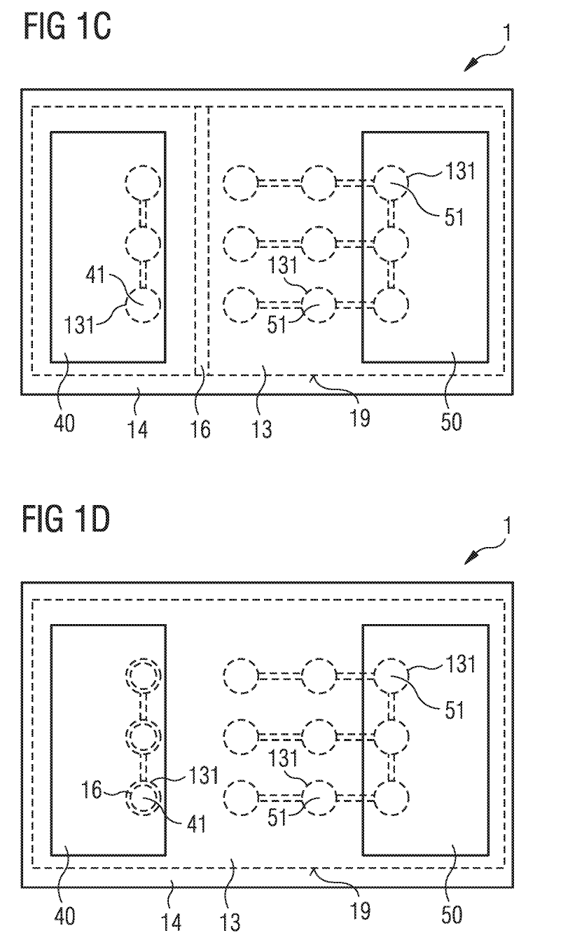

FIGS. 2A to 2C show schematic diagrams of various procedural stages of producing a plurality of semiconductor components 100.

A main body composite 200 with a growth substrate 25 is provided, wherein the semiconductor body 20, the further mirror layer 24, the intermediate layer 23 and the second insulation layer 22 are formed on the growth substrate 25 as shown in FIG. 2A.

FIG. 2B embodies a plurality of recesses 422, a plurality of further recesses 522 and a plurality of separating trenches 27. The recesses 422 extend in the vertical direction through the second insulation layer 22 to the intermediate layer 23. The further recesses 522 extend in the vertical direction through the second insulation layer 22, the intermediate layer 23, the further mirror layer 24, the first semiconductor layer 201 and the active area 202 into the second semiconductor layer 203. A contact insulation 26 is formed in each of the further recesses 522.

In FIG. 2C, the recesses 422 and the further recesses 522 that form the contact elements 42 and the further contact elements 52 are filled with an electrically conductive material, for example, with a metal, for instance copper. A surface of the main body composite 200 facing away from the substrate 25 is planarized and, therefore, an exposed planar contact surface 21 is formed between each of the separating trenches 27.

The main body composite 200 can mechanically connect to a plurality of carriers 1, by a direct bonding method, for example. Before or after bonding of the main body composite 200 with the carriers 1, the semiconductor composite 200 is separated along the separating trenches 27, for example, by lasers and mechanical load (stealth dicing), radiation or by a mechanical and/or chemical separating method. Nevertheless, a plurality of separated main bodies 2 can be attached to a joint carrier composite. In a subsequent method step, the carrier composite can be separated into a plurality of semiconductor components each with one carrier 1.

FIG. 3A shows a schematic sectional view of an example for a semiconductor component 100. The semiconductor component 100 has a carrier 1 and a main body 2, wherein the carrier 1 and the main body 2 mechanically connect to one other on a connecting surface 3.

The carrier 1 described in FIG. 3A corresponds to the carrier shown in FIG. 1A. The main body 2 described in FIG. 3A corresponds to the main body 2 shown in FIG. 1A. The connecting surface 3 is free of any connecting material, for instance any adhesive or soldering material. The semiconductor component 100 can be contacted on the rear side via the connection surface 40 and the further connection surface 50 on the rear side 19 of the carrier 1. The semiconductor component is surface-mountable in formed. The through-contacting structure 4 has a crack along the vertical direction on the connecting surface 3. In other words, the through-contacting structure 4 has a lateral surface with a kink on the connecting surface 3, in particular at a transition from the connection element 41 to the contact element 42 or at a transition from a further connection element 51 to the further contact element 52.

The further contact element 52 has a lateral cross section 520 that tapers in the vertical direction from the connecting surface 3 via the first semiconductor layer 201 towards the second semiconductor layer 203. For example, the steepness of a flank of the further contact element 52 from a vertical angle to the connecting surface is 3° to 5°. Nevertheless, the steepness can also be flatter, in particular 10° to 60° and 30° to 45°.

FIG. 3B shows the semiconductor component 100 viewed from above. FIG. 3B essentially corresponds to FIG. 1B. In contrast thereto, FIG. 3B shows the main body 2. The main body 2 has a smaller base surface than the mirror layer 13. The mirror layer 13 has areas that project in lateral directions beyond the main body 2.

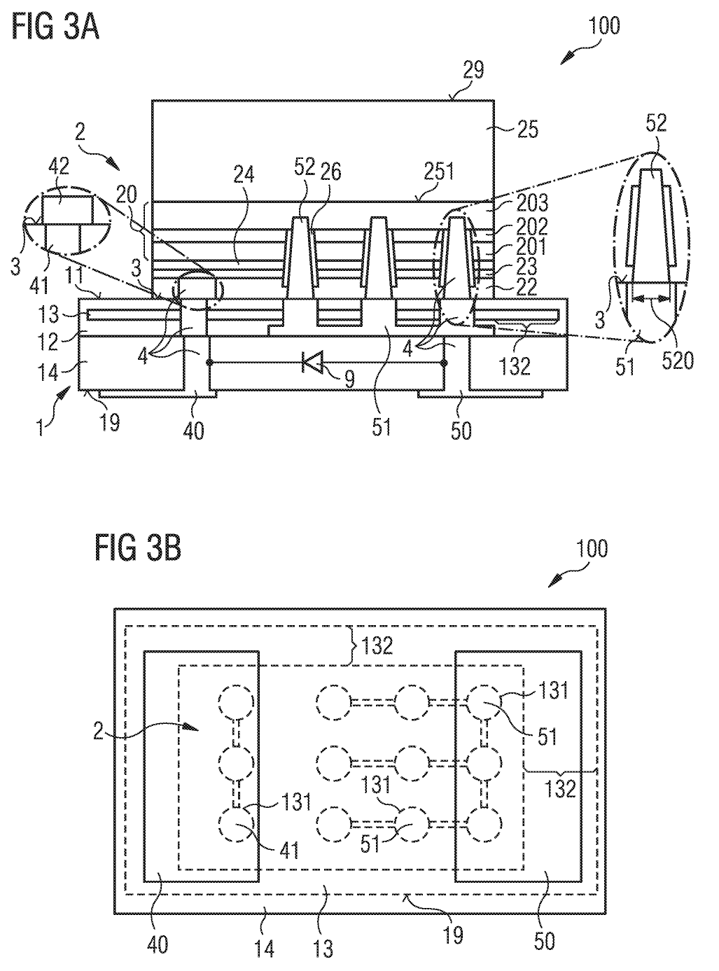

FIGS. 4A to 4C show sectional views of further examples for a semiconductor component 100. Such examples essentially correspond to the example shown in FIG. 3A.

In contrast thereto, the semiconductor component 100 shown in FIG. 4A is free of any growth substrate 25. The main body 2 has a radiation exit surface 29 facing away from the carrier 1.

The semiconductor component 100 shown in FIG. 4B has a structured growth substrate 25, wherein the growth substrate has a structured surface 251 facing the semiconductor body 20 with light out-coupling structural elements 252. A surface of the second semiconductor layer 203 is modelled on the structured surface 251 of the growth substrate 25.

The semiconductor component 100 shown in FIG. 4C is devoid of any growth substrate 25. Furthermore, the semiconductor component 100 has a structured radiation exit surface 29. The example shown in FIG. 4C essentially corresponds to the example shown in FIG. 4B, wherein the structured growth substrate 25 is completely removed.

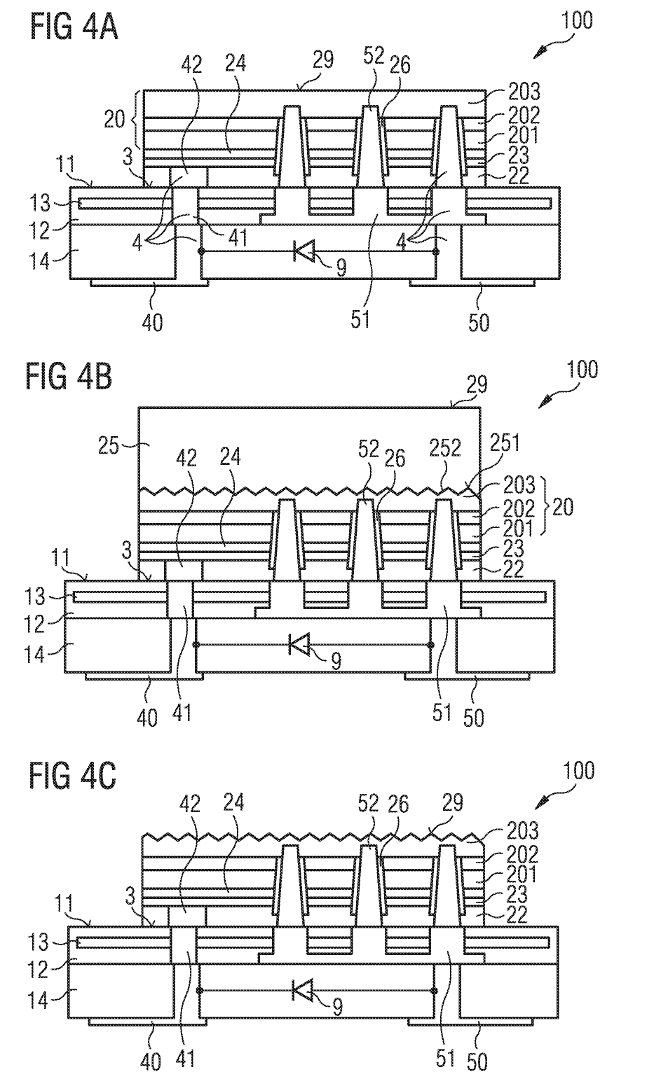

FIGS. 5A and 5B show further examples for a semiconductor component 100.

The example shown in FIG. 5A essentially corresponds to the example shown in FIG. 4C. In contrast thereto, the further contact element 52 extends in the vertical direction laterally relative to the semiconductor body 20, wherein a contact insulation 26 is arranged in the lateral direction between the semiconductor body 20 and the further contact element 52. In the vertical direction the further contact element 52 extends beyond the second semiconductor layer 203 and directly electrically connects to the latter.

The example shown in FIG. 5B essentially corresponds to the example shown in FIG. 5A. In contrast thereto, the semiconductor component has a structured growth substrate 25. The semiconductor body 20 is partially removed, and therefore the further contact element 52, which is arranged in the vertical direction between the carrier 1 and the growth substrate 25, extends to the second semiconductor layer 203 and is adjacent to the latter.

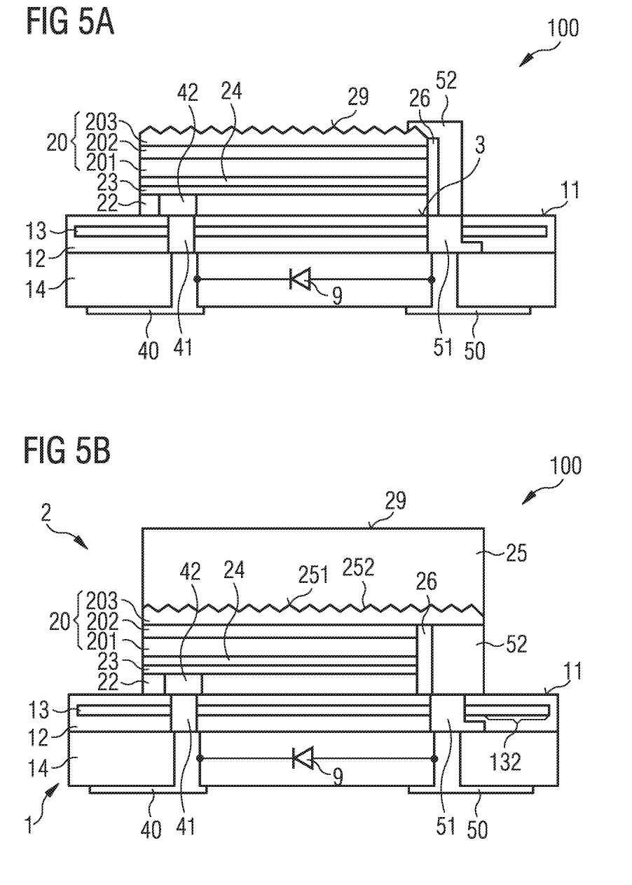

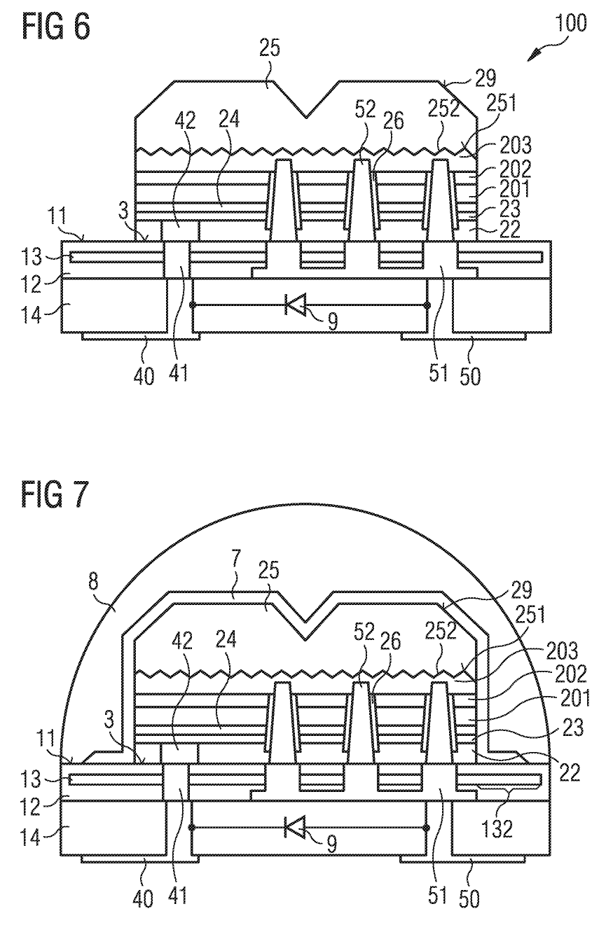

FIGS. 6 and 7 show schematic sectional views of further examples for a semiconductor component 100. The example shown in FIG. 6 essentially corresponds to the example shown in FIG. 4B. In contrast thereto, the growth substrate 25 has a further structured surface, facing away from the structured surface 251, which is formed as the radiation exit surface 29 of the semiconductor component 100.

In FIG. 7 a converter layer 7 is arranged on the structured exit surface 29. When viewing the carrier 1 from above, the converter layer 7 completely covers the main body 2. The areas 132 of the mirror layer 13 projecting beyond the main body 2 are partially covered by the converter layer. In top view, it is also possible that the mirror layer is completely covered by the converter layer. The converter layer 7 comprises in particular a casting mass, for example, a silicon or a resin mass, in which phosphor particles are embedded.

The converter layer 7 completely covers lateral surfaces of the main body 2. In particular, the converter layer may include light-reflecting particles, for instance titanium oxide. The converter layer can be attached to the main body 2 and the carrier 1 in a flat manner, for example, by spraying, molding or dispensing. The converter layer 7 can be of lenticular shape.

The semiconductor component 100 shown in FIG. 7 has an optical element 8. The converter layer 7 is arranged between the main body 2 and the optical element 8. When viewing the carrier from above, the optical element 8 completely covers the converter layer 7 and the main body 2. The optical element 8 is in particular of lenticular shape. The optical element 8 can, for example, be attached to the main body 2 and to the carrier 1 by molding or dispensing a thixotropic or highly viscous material.

The converter layer 7 and/or the optical element 8 can be formed in individual semiconductor components 100 before or after the separation. For example, the main body composite 200 can mechanically connect to a carrier composite by a direct bonding method. A joint growth substrate is in particular separated into a plurality of growth substrates 25 along the separating ditches 27. The converter layer 7 and/or the optical element 8 can in particular be formed such that the carrier composite in areas of the separating ditches are at least partially uncovered, and therefore the converter layer 7 and/or the optical element 8 subsequently do not need to be severed during the separation of the carrier composite and of the main body composite into a plurality of semiconductor components 100 each with one carrier 1 and one main body 2.

The converter layer 7 and the optical element 8 of the example shown in FIG. 7 can also be used in FIGS. 3A to 6.

This application claims priority of DE 10 2014 100 773.5, the disclosure of which is hereby incorporated by reference.

Our components and methods are not limited by the description on the basis of the examples. Instead, this disclosure comprises every new feature as well as every combination of features, which in particular includes every combination of features included in the appended claims, even if such feature or such combination is not explicitly specified itself in the claims or examples.

1.-19. (canceled)

20. A method of producing a semiconductor component comprising:
A) providing a carrier with a first insulation layer, a mirror layer at least partially covered by the first insulation layer and a connection element, wherein the carrier comprises an exposed planar mounting surface and the connection element extends through the first insulation layer to the mounting surface,
B) providing a main body with a semiconductor body, a second insulation layer and a contact element to electrically contact the semiconductor body, wherein the main body has an exposed planar contact surface and the contact element extends through the second insulation layer to the contact surface, and
C) connecting the main body to the carrier, wherein the planar contact surface and the planar mounting surface are brought together to form a connecting surface, and the contact element and the connection element electrically connect with one another.

21. The method according to claim 20, wherein the carrier and the main body connect to one another by a direct bonding method in which the connecting surface formed between the carrier and the main body is devoid of connecting material.

22. The method according to claim 20, in which the planar contact surface is contiguous, in top view, completely covers the semiconductor body and has a roughness equaling 10 nm maximum.

23. The method according to claim 20, wherein the insulation layers each comprise an oxide, the connection element and the contact element each comprise a metal and the connecting surface is partially formed by an oxide, a metal-metal and an oxide-metal interface.

24. The method according to claim 20, in which the mirror layer is completely embedded within the first insulation layer.

25. The method according to claim 20, in which the mirror layer is flat and formed in the lateral direction such that, when the carrier is viewed from above, the mirror layer projects laterally beyond the main body.

26. The method according to claim 20, in which the semiconductor body has an active area and at least one further contact element is introduced into the main body, the further contact element extending from the contact surface through the second insulation layer and through the active area, wherein the further contact element is laterally surrounded by a contact isolation on all sides to electrically isolate the further contact element from the active area.

27. The method according to claim 20, in which a converter layer is attached to the main body and the carrier following C), wherein, in top view, the converter layer completely covers the main body and at least partially covers areas of the mirror layer laterally to the main body.

28. The method according to claim 20, in which the semiconductor body is applied onto a growth substrate in layers, and in a next method step the growth substrate is thinned or completely removed.

29. A semiconductor component comprising a carrier, a main body arranged on the carrier and a through-contacting structure, in which
the carrier has a first insulation layer, a mirror layer at least partially covered by the first insulation layer and a connection element extending through the first insulation layer, wherein the mirror layer is flat and, in top view, projects laterally beyond the main body,
the main body has a semiconductor body, a second insulation layer and a contact element extending through the second insulation layer,
the carrier and the main body connect together on the insulation layers, wherein a connecting surface is formed between the insulation layers, the connecting surface being devoid of connecting material, and
the through-contacting structure extends in the vertical direction through the carrier and comprises the connection element as well as the contact element, wherein the connection element and contact element are adjacent to each other on the connecting surface.

30. The semiconductor component according to claim 29, in which the mirror layer is completely embedded in the first insulation layer.

31. The semiconductor component according to claim 29, in which the mirror layer has an opening through which the through-contacting layer extends.

32. The semiconductor component according to claim 29, in which the main body comprises an active area, a contact insulation and a further contact element, wherein
the further contact element extends through the second insulation layer and through the active area, and
the contact insulation laterally surrounds the further contact element on all sides for insulating the further contact element against the active area.

33. The semiconductor component according to claim 29, in which the semiconductor component can be electrically contacted on the rear side via a rear side of the carrier facing away from the main body.

34. The semiconductor component according to claim 29 having a converter layer, wherein, when viewing the semiconductor component from above, the converter layer completely covers the main body and at least partially covers areas of the mirror layer laterally to the main body.

35. The semiconductor component according to claim 29, in which the semiconductor body comprises a first semiconductor layer, a second semiconductor layer and an active area arranged between the semiconductor layers, and
the main body comprises at least a further contact element extending from the connecting surface through the second insulation layer, the first semiconductor layer and the active area into the second semiconductor layer, wherein the further contact element is laterally surrounded by a contact isolation on all sides to electrically isolate the further contact element from the active area.

36. The semiconductor component according to claim 32, wherein the further contact element has a lateral cross section that tapers in the vertical direction from the first semiconductor layer towards the second semiconductor layer.

37. The semiconductor component according to claim 29, further comprising a protective element in which the protective element is integrated in the carrier and electrically connects in parallel with the semiconductor body via the through-contacting structure.

38. The semiconductor component according to claim 29, in which the main body comprises a growth substrate, on which the semiconductor body is deposited in layers, wherein the growth substrate has a structured surface facing the semiconductor body.

39. A semiconductor component comprising a carrier, a main body arranged on the carrier and a through-contacting structure, in which
the carrier has a first insulation layer and a connection element extending through the first insulation layer,
the main body has a semiconductor body, a second insulation layer and a contact element extending through the second insulation layer such that a contact surface is formed by surfaces of the contact element and of the second insulation layer,
the carrier and the main body connect together on the insulation layers, wherein a connecting surface is formed between the first and the second insulation layers,
the connecting surface is formed by the contact surface and is devoid of connecting material, and
the through-contacting structure extends in the vertical direction through the carrier and comprises the connection element and the contact element, wherein the connection element and contact element are adjacent to each other on the connecting surface.
